(19) United States
(12) Patent Application Publication
(10) Pub. No.: US 2013/0319847 A1
(43) Pub. Date: Dec. 5, 2013

(54) METHODS AND APPARATUSES FOR LOW RESISTIVITY Ag THIN FILM USING COLLIMATED SPUTTERING

(71) Applicants: Guowen Ding, San Jose, CA (US); Mohd Fadzli Anwar Hassan, San Francisco, CA (US); Hien Minh Huu Le, San Jose, CA (US); Zhi-Wen Sun, Sunnyvale, CA (US)

(72) Inventors: Guowen Ding, San Jose, CA (US); Mohd Fadzli Anwar Hassan, San Francisco, CA (US); Hien Minh Huu Le, San Jose, CA (US); Zhi-Wen Sun, Sunnyvale, CA (US)

(73) Assignee: Intermolecular, Inc., San Jose, CA (US)

(21) Appl. No.: 13/489,079

(22) Filed: Jun. 5, 2012

(51) Int. Cl. C23C 14/34; C23C 14/14; C23C 14/08

(52) U.S. Cl. 204/192.1; 204/298.11

(57) ABSTRACT

A method for making low emissivity panels, comprising forming highly smooth layers of silver on highly smooth layers of base or seed films. The highly smooth layers can be achieved by collimated sputtering, lowering the angular distribution of the sputtered particles when reaching the substrate.

### FIELD OF THE INVENTION

The present invention relates generally to films providing high transmittance and low emissivity, and more particularly to such films deposited on transparent substrates.

### BACKGROUND OF THE INVENTION

Sunlight control glasses are commonly used in applications such as building glass windows and vehicle windows, typically offering high visible transmission and low emissivity. High visible transmission can allow more sunlight to pass through the glass windows, thus being desirable in many window applications. Low emissivity glass can block infrared (IR) radiation to reduce undesirable interior heating.

In low emissivity glasses, IR radiation is mostly reflected with minimum absorption and emission, thus reducing the heat transferring to and from the low emissivity surface. Low emissivity, or low-e, panels are often formed by depositing a reflective layer (e.g., silver) onto a substrate, such as glass. The overall quality of the reflective layer, such as with respect to texturing and crystallographic orientation, is important for achieving the desired performance, such as high visible light transmission and low emissivity (i.e., high heat reflection). In order to provide adhesion, as well as protection, several other layers are typically formed both under and over the reflective layer. The various layers typically include dielectric layers, such as silicon nitride, tin oxide, and zinc oxide, to provide a barrier between the stack and both the substrate and the environment, as well as to act as optical fillers and function as anti-reflective coating layers to improve the optical characteristics of the panel.

One known method to achieve low emissivity is to form a relatively thick silver layer. However, as the thickness of the silver layer increases, the visible light transmission of the reflective layer is reduced, as is manufacturing throughput, while overall manufacturing costs are increased. Therefore, is it desirable to form the silver layer as thin as possible, while still providing emissivity that is suitable for low-e applications.

### SUMMARY OF THE DISCLOSURE

In some embodiments, the present invention discloses a method for making low emissivity panels, comprising forming layers of silver on layers of base or seed films. The layers can be achieved by collimated sputtering, lowering the angular distribution of the sputtered particles when reaching the substrate.

In some embodiments, the present invention discloses depositing a seed layer using collimated sputtering to achieve a thin smooth layer. An infrared reflective layer comprising silver can be deposited on the smooth seed layer, preferably also using collimated sputtering to reduce roughness. Metallic barrier layer can be deposited on the silver layer, preferably using collimated sputtering.

In some embodiments, the present invention discloses methods for making low emissivity panels in large area coaters. A moving mechanism can be provided to move a substrate forward under one or more sputter targets, to deposit seed, infrared reflective layers, together with other layers. A collimator can be positioned between the targets and the substrate to reduce the angular distribution of the sputter particles, helping to improve the smoothness of the deposited layer, especially at thin thickness.

In some embodiments, the present invention discloses apparatuses for making low emissivity panels, comprising collimators disposed between sputtered targets and a substrate. A moving mechanism can be included to provide an in-line large area coater system.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale.

The techniques of the present invention can readily be understood by considering the following detailed description in conjunction with the accompanying drawings, in which:

FIG. 1A illustrates an exemplary thin film coating according to some embodiments of the present invention.

FIG. 1B illustrates a low emissivity transparent panel according to some embodiments of the present invention.

FIG. 2 provides a simplified illustration of a prior art physical vapor deposition (PVD) system.

FIGS. 3A-3B illustrate exemplary deposition configurations according to some embodiments of the present invention.

FIG. 4 illustrates an exemplary deposition system comprising a collimator according to some embodiments of the present invention.

FIG. 5 illustrates an exemplary in-line deposition system according to some embodiments of the present invention.

FIGS. 6A-6B illustrate an exemplary collimator according to some embodiments of the present invention.

FIG. 7 illustrates an exemplary flow chart for collimated sputtering according to some embodiments of the present invention.

FIG. 8 illustrates another exemplary flow chart for collimated sputtering according to some embodiments of the present invention.

FIG. 9 illustrates exemplary sheet resistance for low emissivity stacks according to some embodiment of the present invention.

### DETAILED DESCRIPTION OF THE PREFERRED EMBODIMENTS

A detailed description of one or more embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

In some embodiments, the present invention discloses methods and apparatuses for making low emissivity panels, comprising forming smooth layers of a conductive material (such as silver, gold or copper) on smooth layers of base or seed films, such as ZnO, SnO or an alloy oxide. In some embodiments, the silver layer, seed layer, or base layer can be formed by collimated sputtering, lowering the angular distribution of the sputtered particles when reaching the substrate. For example, the sputtered particles can be confined to within a sputtering angle of less than 0.25 steradians.

In some embodiments, the present invention discloses methods and apparatuses for making low emissivity panels which comprise a low resistivity thin infrared reflective layer comprising a conductive material such as silver, gold, or copper. The thin silver layer can be thinner than about 10 nm, such as about 7 or 8 nm, and can have resistivity lower than about 4.5 μΩ-cm. The silver layer can be smooth, e.g., having low roughness, and is preferably deposited on another smooth seed layer. The present low emissivity panels can have improved overall quality of the infrared reflective layer with respect to conductivity, physical roughness and thickness. For example, the methods allow for improved conductivity of the reflective layer such that the thickness of the reflective layer may be reduced while still providing desirably low emissivity.

In general, the reflective layer preferably has low sheet resistance, since low sheet resistance is related to low emissivity. In addition, the reflective layer is preferably thin to provide high visible light transmission. Thus in some embodiments, the present invention discloses methods and apparatuses to deposit a smooth reflective layer, providing a thin reflective layer with low sheet resistance. The present methods can also maximize volume production, throughput, and efficiency of the manufacturing process used to form low emissivity panels.

In some embodiments, the present invention discloses an improved coated transparent panel, such as a coated glass, that has acceptable visible light transmission and IR reflection. The present invention also discloses methods of producing the improved, coated, transparent panels, which comprise specific layers in a coating stack.

The coated transparent panels can comprise a glass substrate or any other transparent substrates, such as substrates made of organic polymers. The coated transparent panels can be used in window applications such as vehicle and building windows, skylights, or glass doors, either in monolithic glazings or multiple glazings with or without a plastic interlayer or a gas-filled sealed interspace.

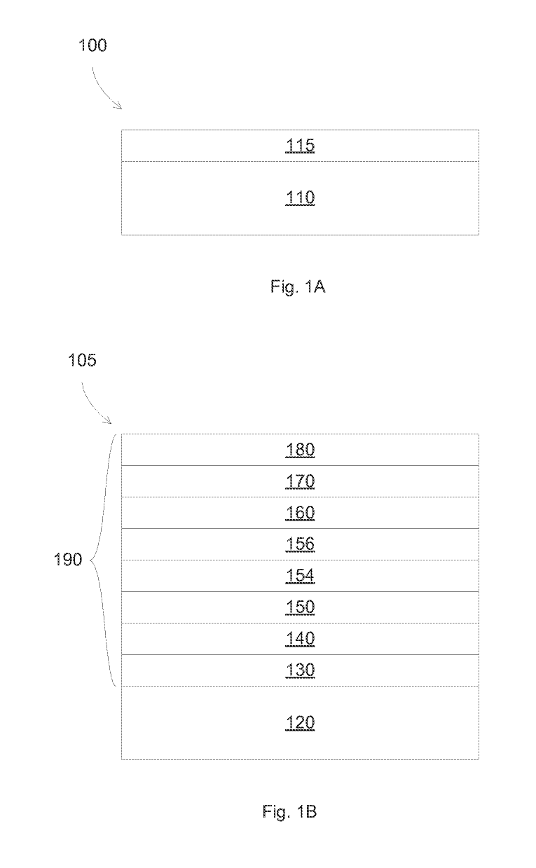

FIG. 1A illustrates an exemplary thin film coating according to some embodiments of the present invention. A smooth layer 115 is disposed on a substrate 110 to form a coated transparent panel 100, which has high visible light transmission, and low IR emission.

The layer 115 can be sputtered deposited using different processes and equipment, for example, the targets can be sputtered under direct current (DC), pulsed DC, alternate current (AC), radio frequency (RF) or any other suitable conditions. In some embodiments, the present invention discloses a physical vapor deposition method for depositing a smooth layer 115. In some embodiments, the method comprises limiting the distribution angle of the sputtered particles between the target and the substrate 110. For example, a screen, a shield or a collimator with holes can be used to restrict the direction of the sputtered particles that can reach the substrate. The processing can comprise a gas mixture introduced to a plasma ambient to sputtering material from one or more targets disposed in the processing chamber. The sputtering process can further comprise other components such as magnets for confining the plasma, and utilize different process conditions such as DC, AC, RF, or pulse sputtering.

In some embodiments, the smooth layer 115 can comprise a base layer, an oxide layer, a seed layer, a conductive layer, a barrier layer, an antireflective layer, or a protective layer. In some embodiments, the present invention discloses a high transmittance, low emissivity coated article comprising a transparent substrate, and a smooth metallic reflective film comprises one of silver, gold, or copper.

In some embodiments, the present invention discloses a coating stack, comprising multiple layers for different functional purposes. For example, the coating stack can comprise a seed layer to facilitate the deposition of the reflective layer, an oxygen diffusion barrier layer disposed on the reflective layer to prevent oxidation of the reflective layer, a protective layer disposed on the substrate to prevent physical or chemical abrasion, or an antireflective layer to reduce visible light reflection. The coating stack can comprise multiple layers of reflective layers to improve IR emissivity.

FIG. 1B illustrates a low emissivity transparent panel 105 according to some embodiments of the present invention. The low emissivity transparent panel can comprise a glass substrate 120 and a low-e stack 190 formed over the glass substrate 120. The glass substrate 120 in one embodiment is made of a low emissivity glass, such as borosilicate glass, and has a thickness of, for example, between 1 and 10 millimeters (mm). The substrate 120 may be square or rectangular and about 0.5-2 meters (m) across. In some embodiments, the substrate 120 may be made of, for example, plastic or polycarbonate.

The low-e stack 190 includes a lower protective layer 130, a lower oxide layer 140, a seed layer 150, a reflective layer 154, a barrier layer 156, an upper oxide 160, an optical filler layer 170, and an upper protective layer 180. Some layers can be optional, and other layers can be added, such as interface layer or adhesion layer. Exemplary details as to the functionality provided by each of the layers 130-180 are provided below.

The various layers in the low-e stack 190 may be formed sequentially (i.e., from bottom to top) on the glass substrate 120 using a physical vapor deposition (PVD) and/or reactive (or plasma enhanced) sputtering processing tool. In one embodiment, the low-e stack 190 is formed over the entire glass substrate 120. However, in other embodiments, the low-e stack 190 may only be formed on isolated portions of the glass substrate 120.

The lower protective layer 130 is formed on the upper surface of the glass substrate 120. The lower protective layer 130 can comprise silicon nitride, silicon oxynitride, or other nitride material such as SiZrN, for example, to protect the other layers in the stack 190 from diffusion from the substrate 120 or to improve the haze reduction properties. In some embodiments, the lower protective layer 130 is made of silicon nitride and has a thickness of, for example, between about 10 nm to 50 nm, such as 25 nm.

The lower oxide layer 140 is formed on the lower protective layer 130 and over the glass substrate 120. The lower oxide layer is preferably a metal oxide or metal alloy oxide layer and can serve as an antireflective layer. The lower metal oxide layer 140 may enhance the crystallinity of the reflective layer 154, as is described in greater detail below.

The seed layer 150 can be used to provide a seed layer for the IR reflective film, for example, a zinc oxide layer deposited before the deposition of a silver reflective layer can provide a silver layer with lower resistivity, which can improve its reflective characteristics. The seed layer can comprise zinc oxide, nickel oxide, nickel chrome oxide, nickel alloy oxides, chrome oxides, or chrome alloy oxides.

In some embodiments, the seed layer 150 can be made of a metal, such as titanium, zirconium, and/or hafnium, and has a thickness of, for example, 50 Å or less. Generally, seed layers are relatively thin layers of materials formed on a surface (e.g., a substrate) to promote a particular characteristic of a subsequent layer formed over the surface (e.g., on the seed layer). For example, seed layers may be used to affect the crystalline structure (or crystallographic orientation) of the subsequent layer, which is sometimes referred to as “templating.” More particularly, the interaction of the material of the subsequent layer with the crystalline structure of the seed layer causes the crystalline structure of the subsequent layer to be formed in a particular orientation.

For example, a metal seed layer is used to promote growth of the reflective layer in a particular crystallographic orientation. In a particular embodiment, the metal seed layer is a material with a hexagonal crystal structure and is formed with a <002> crystallographic orientation which promotes growth of the reflective layer in the <111> orientation when the reflective layer has a face centered cubic crystal structure (e.g., silver), which is preferable for low-e panel applications.

In some embodiments, the seed layer 150 can be continuous and covers the entire substrate. Alternatively, the seed layer 150 may not be formed in a completely continuous manner. The seed layer can be distributed across the substrate surface such that each of the seed layer areas is laterally spaced apart from the other seed layer areas across the substrate surface and do not completely cover the substrate surface. For example, the thickness of the seed layer 150 can be a monolayer or less, such as between 2.0 and 4.0 Å, and the separation between the layer sections may be the result of forming such a thin seed layer (i.e., such a thin layer may not form a continuous layer).

The reflective layer 154 is formed on the seed layer 150. The IR reflective layer can be a metallic, reflective film, such as gold, copper, or silver. In general, the IR reflective film comprises a good electrical conductor, blocking the passage of thermal energy. In some embodiments, the reflective layer 154 is made of silver and has a thickness of, for example, 100 Å. Because the reflective layer 154 is formed on the seed layer 150, for example, due to the <002> crystallographic orientation of the seed layer 150, growth of the silver reflective layer 154 in a <111> crystalline orientation is promoted, which offers low sheet resistance, leading to low panel emissivity.

Because of the promoted <111> texturing orientation of the reflective layer 154 caused by the seed layer 150, the conductivity and emissivity of the reflective layer 154 is improved. As a result, a thinner reflective layer 154 may be formed that still provides sufficient reflective properties and visible light transmission. Additionally, the reduced thickness of the reflective layer 154 allows for less material to be used in each panel that is manufactured, thus improving manufacturing throughput and efficiency, increasing the usable life of the target (e.g., silver) used to form the reflective layer 154, and reducing overall manufacturing costs.

Further, the seed layer 150 can provide a barrier between the metal oxide layer 140 and the reflective layer 154 to reduce the likelihood of any reaction of the material of the reflective layer 154 and the oxygen in the lower metal oxide layer 140, especially during subsequent heating processes. As a result, the resistivity of the reflective layer 154 may be reduced, thus increasing performance of the reflective layer 154 by lowering the emissivity.

Formed on the reflective layer 154 is a barrier layer 156, which can protect the reflective layer 154 from being oxidized. For example, the barrier layer can be a diffusion barrier, stopping oxygen from diffusing into the silver layer from the upper oxide layer 160. The barrier layer 156 can comprise titanium, nickel or a combination of nickel and titanium.

Formed on the barrier layer 156 is an upper oxide layer 160, which can function as an antireflective film stack, including a single layer or multiple layers for different functional purposes. The antireflective layer 160 serves to reduce the reflection of visible light, selected based on transmittance, index of refraction, adherence, chemical durability, and thermal stability. In some embodiments, the antireflective layer 160 comprises tin oxide, offering high thermal stability properties. The antireflective layer 160 can comprise titanium dioxide, silicon nitride, silicon dioxide, silicon oxynitride, niobium oxide, SiZrN, tin oxide, zinc oxide, or any other suitable dielectric material.

Formed on the antireflective layer 160 is an optical filler layer 170. The optical filler layer 170 can be used to provide a proper thickness to the low-e stack, for example, to provide an antireflective property. The optical filler layer preferably has high visible light transmittance. In some embodiments, the optical filler layer 170 is made of tin oxide and has a thickness of, for example, 100 Å. The optical filler layer may be used to tune the optical properties of the low-e panel 105. For example, the thickness and refractive index of the optical filler layer may be used to increase the layer thickness to a multiple of the incoming light wavelengths, effectively reducing the light reflectance and improving the light transmittance.

Formed on the optical filler layer 170 is an upper protective layer 180. An upper protective layer 180 can be used for protecting the total film stack, for example, to protect the panel from physical or chemical abrasion. The upper protective layer 180 can be an exterior protective layer, such as silicon nitride, silicon oxynitride, titanium oxide, tin oxide, zinc oxide, niobium oxide, or SiZrN.

In some embodiments, adhesion layers can be used to provide adhesion between layers. The adhesion layers can be made of a metal alloy, such as nickel-titanium, and have a thickness of, for example, 30 Å.

It should be noted that depending on the exact materials used, some of the layers of the low-e stack 190 may have some materials in common. An example of such a stack may use a zinc-based material in the oxide dielectric layers 140 and 160. As a result, a relatively low number of different targets can be used for the formation of the low-e stack 190.

In some embodiments, the coating can comprise a double or triple layer stack, having multiple IR reflective layers. In some embodiments, the layers can be formed using a plasma enhanced, or reactive sputtering, in which a carrier gas (e.g., argon) is used to eject ions from a target, which then pass through a mixture of the carrier gas and a reactive gas (e.g., oxygen), or plasma, before being deposited.

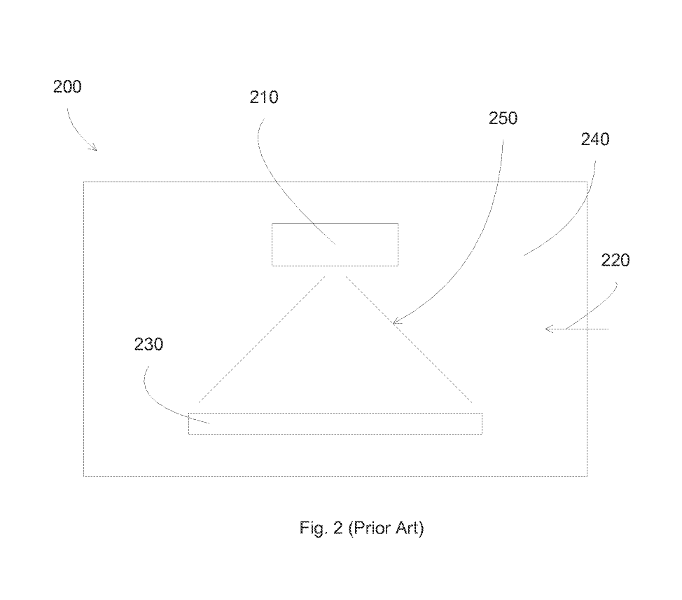

FIG. 2 provides a simplified illustration of a prior art physical vapor deposition (PVD) system. The PVD system 200 includes a housing that defines, or encloses, a processing chamber 240, a substrate 230, a target assembly 210, and reactive species delivered from an outside source 220. During deposition, the target is bombarded with argon ions, which releases sputtered particles in all directions toward the substrate 230. The angular distribution 250 of the sputtered particles from the target 210 to the substrate 230 can be large, potentially resulting in side deposition, leading to possible uneven growth of the deposited film, increasing its surface roughness.

In some embodiments, the present invention discloses methods and apparatuses for making thin smooth layers, comprising restricting the sputtered particles from the target to the substrate. For example, the sputtered particles can be confined to reach the substrate in a substantially vertical direction, which can enhance uniform columnar growth across the substrate, reducing thin film surface roughness.

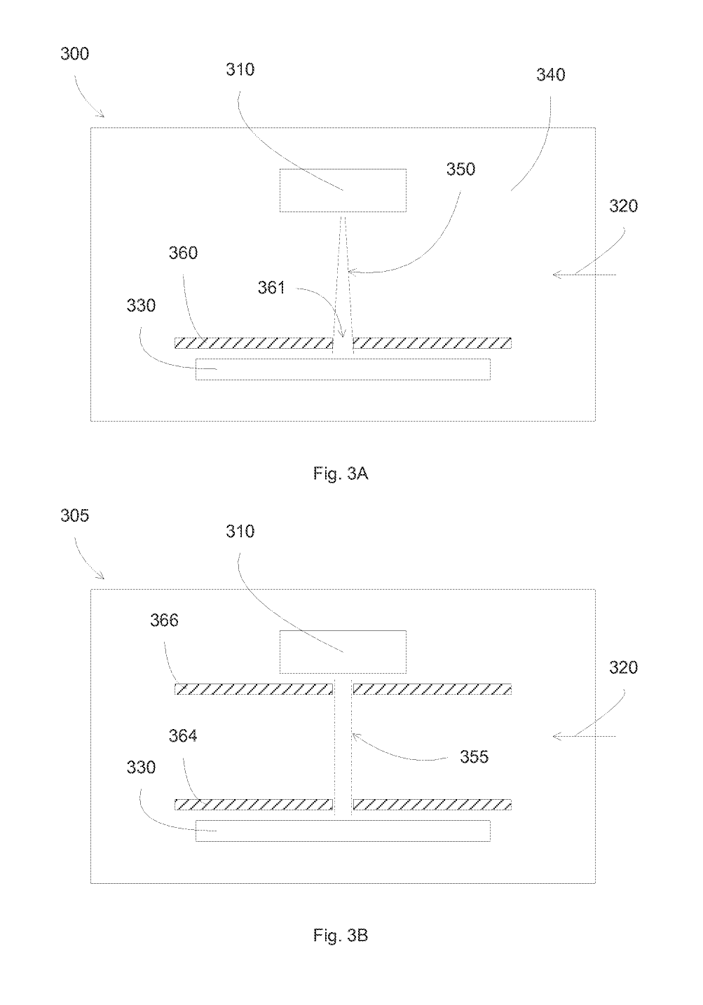

FIGS. 3A-3B illustrate exemplary deposition configurations according to some embodiments of the present invention. In FIG. 3A, a sputter deposition system 300 comprises a target assembly 310 disposed in a housing 340, containing reactive species delivered from an outside source 320. The target assembly 310 generally includes one or more materials that are to be used to deposit a layer of material on the upper surface of the substrate 330. The substrate can be stationary, or in some manufacturing environments, the substrate may be in motion during the deposition processes.

The materials used in the target assembly 310 may, for example, include tin, zinc, magnesium, aluminum, lanthanum, yttrium, titanium, antimony, strontium, bismuth, silicon, silver, nickel, chromium, or any combination thereof (i.e., a single target may be made of an alloy of several metals). Additionally, the materials used in the targets may include oxygen, nitrogen, or a combination of oxygen and nitrogen in order to form the oxides, nitrides, and oxynitrides described above. Additionally, although only one target assembly 310 is shown, additional target assemblies may be used. As such, different combinations of targets may be used to form, for example, the dielectric layers described above. For example, in an embodiment in which the dielectric material is zinc-tin-titanium oxide, the zinc, the tin, and the titanium may be provided by separate zinc, tin, and titanium targets, or they may be provided by a single zinc-tin-titanium alloy target. For example, the target assembly 310 can comprise a silver target, and together with argon ions, sputter deposit a silver layer on substrate 330. The target assembly 310 can comprise a metal or metal alloy target, such as tin, zinc, or tin-zinc alloy, and together with reactive species of oxygen to sputter deposit a metal or metal alloy oxide layer.

The sputter deposition system 300 can comprise other components, such as a substrate support for supporting the substrate. The substrate support can comprise a vacuum chuck, electrostatic chuck, or other known mechanisms. The substrate support can be capable of rotating around an axis thereof that is perpendicular to the surface of the substrate. In addition, the substrate support may move in a vertical direction or in a planar direction. It should be appreciated that the rotation and movement in the vertical direction or planar direction may be achieved through known drive mechanisms which include magnetic drives, linear drives, worm screws, lead screws, a differentially pumped rotary feed through drive, etc.

In some embodiments, the substrate support includes an electrode which is connected to a power supply, for example, to provide a RF or dc bias to the substrate, or to provide a plasma environment in the process housing 340. The target assembly 310 can include an electrode which is connected to a power supply to generate a plasma in the process housing. The target assembly 310 is preferably oriented towards the substrate 330.

The sputter deposition system 300 can also comprise a power supply coupled to the target electrode. The power supply provides power to the electrodes, causing material to be, at least in some embodiments, sputtered from the target. During sputtering, inert gases, such as argon or krypton, may be introduced into the processing chamber 340 through the gas inlet 320. In embodiments in which reactive sputtering is used, reactive gases may also be introduced, such as oxygen and/or nitrogen, which interact with particles ejected from the targets to form oxides, nitrides, and/or oxynitrides on the substrate.

The sputter deposition system 300 can also comprise a control system having, for example, a processor and a memory, which is in operable communication with the other components and configured to control the operation thereof in order to perform the methods described herein.

In some embodiments, the sputter deposition system 300 comprises a shield 360 having an aperture 361 through which a portion of a surface of the substrate 330 is exposed for deposition. The aperture 361 can be used that may be used to confine or limit the sputtered particles reaching the substrate 330. For example, the generated plasma will dislodge particles from the target to be deposited on the exposed surface of the substrate. The shield 360 together with the aperture 361 can imposes limitations on the direction 350 of the movement of the sputtered particles between the target and the substrate, resulting in smoother deposited layer.

In some embodiments, the shield 360 is preferably disposed in a close proximity to the substrate, for example, less than 5 cm or preferably less than 1 or 2 cm. In some embodiments, the shield 360 can further comprise a sleeve portion covering the sidewalls of the process housing. The shield 360 can comprise one or more apertures 361 for depositing on multiple areas of the substrate.

In some embodiments, the sputter deposition system can comprise a double shield between the target and the substrate. The shield can have one or more openings, arranged to deposit on one or more areas of the substrate, which can be overlapped or non-overlapped. FIG. 3B shows a sputter deposition system 305 comprising a first shield 364 disposed near the substrate together with a second shield 366 disposed near the target assembly 310. The sputtered particles are then confined between the two shields, having the angle of distribution 355 limited to be substantially perpendicular to the substrate. The two shields can be disposed anywhere between the target and the substrate, and does not have to be positioned in close vicinity of the substrate.

In some embodiments, the sputter deposition system can comprise a collimator between the target and the substrate. The collimator can have one or more openings, arranged to deposit on multiple areas of the substrate. Alternatively, the collimator can comprise a shield having high aspect ratio openings. The collimator can be positioned anywhere between the target and the substrate, and can be positioned in a vicinity of the substrate to further reduce angular spreading.

In some embodiments, the present invention discloses a method of forming a thin layer which comprises placing a collimator between a target and a substrate to impose limitations on the direction of movement of the sputtered particles, and forming a thin layer on the substrate.

Collimated sputtering can produce a columnar structure exhibited by the deposited layer. The columnar structure allows for film growth uniformly on the surface, reducing the irregular roughness of the deposited film, especially at low thickness, the resulting layers having smooth surfaces. The smooth surface can be characterized by a peak-to-valley roughness of less than about 10% of the thickness.

The collimator can have a plurality of apertures, typically in columnar shapes. The apertures form conduit along the thickness of the collimator, thus having the length of the apertures equal to the thickness of the collimator. An important characteristic of the collimator is its aspect ratio, which is defined as the ratio of the thickness of the collimator plate over the diameter of the apertures. When the collimator has an aspect ratio of 1, the passage rate for angles around 0.25 steradians is approximately 50%. When the aspect ratio of the collimator is 1, the direction which allows the sputtered particles to pass through ranges from 0 to 0.25 steradians. Since the target plate and the collimator plate are placed in parallel in a sputtering chamber, mainly particles emitted from the target with angles within the above range pass through the collimator.

The collimator can reduce the number of sputtered particles passing through, in which the passage rate of the sputtered particles depends on the angle of the sputtered particles incident on the collimator plate. In general, a high aspect ratio of the collimator can lead to more of the sputtered particles being captured by the collimator. For example, with an aspect ratio of 1, the particle passage rate for angles around 0.25 steradians is about 50%, with the direction which allows the sputtered particles to pass through ranging from 0 to 0.25 steradians. In some embodiments, the target and the collimator are parallel, and thus sputtered particles emitted from the target with angles within the above range pass through the collimator.

To improve the efficiency of the collimator, the targets can be particularly designed to match collimated sputtering. For example, a titanium target has a crystal orientation wherein the sputtering surfaces are greatly orientated in the (002) plane.

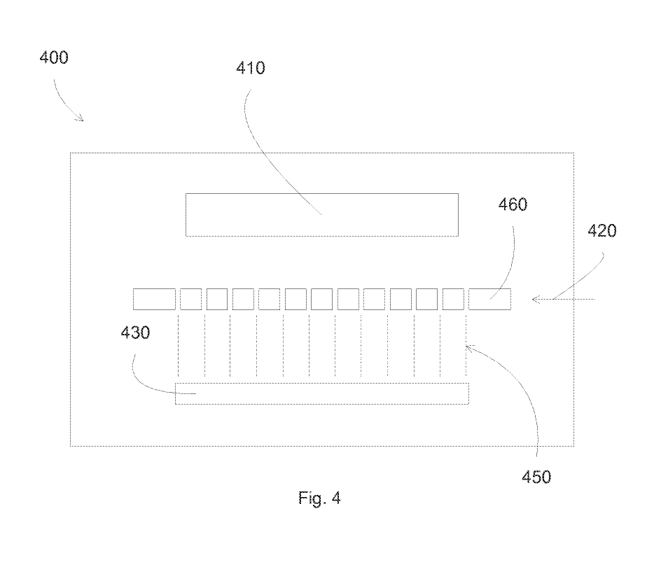

FIG. 4 illustrates an exemplary deposition system comprising a collimator according to some embodiments of the present invention. A sputter deposition system 400 comprises a target assembly 410 disposed in a housing, containing reactive species delivered from an outside source 420. The target assembly 410 includes a target to be used to deposit a layer of material on the surface of a substrate 430.

The sputter deposition system 400 further comprises a collimator 460 disposed between the target 410 and the substrate 430. The sputtered particles are then delivered to the substrate in a substantially parallel direction 450, forming a smooth, thin, deposited layer on the substrate surface.

In some embodiments, the present invention discloses an in-line deposition system, comprising a transport mechanism for moving substrates between deposition stations. In some deposition stations, a collimator can be provided to generate smooth deposited films.

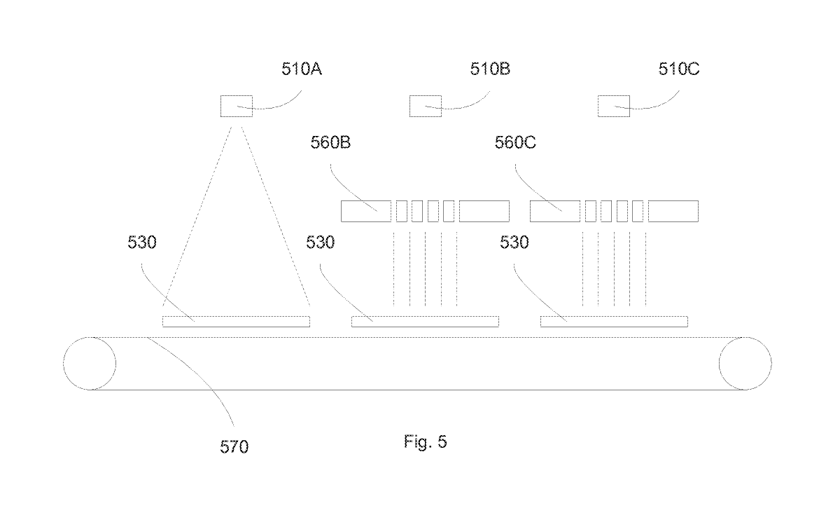

FIG. 5 illustrates an exemplary in-line deposition system according to some embodiments of the present invention. A transport mechanism 570, such as a conveyor belt or a plurality of rollers, can transfer substrate 530 between different sputter deposition stations. For example, the substrate can be positioned at station #1, comprising a target assembly 510A, then transferred to station #2, comprising target assembly 510B and collimator 560B, and then transferred to station #3, comprising target assembly 510C and collimator 560C. The station #1 comprising target 510A is a conventional sputtering station, sputtering particles in all directions without any restriction. The stations #2 and #3 comprising target assemblies 510B and 510C are collimated sputtering stations, and further comprise collimators 560B and 560C to limit the direction of the sputtering particles. Other configurations of sputter stations can be used, such as all collimated sputtering stations, or only one collimated sputtering station. In addition, other stations can be included, such as input and output stations, or anneal stations.

In some embodiments, the collimator comprises a plurality of openings, wherein the openings are staggered so that a deposited layer is continuous along a direction not parallel to the moving direction of the substrate. The sizes of the openings are configured to lower the angular distribution of the sputtered particles to achieve a desired film smoothness. The staggered collimator is configured to deposit a band of material on the substrate through the openings, enabling in-line large area coating while the substrate is moving forward.

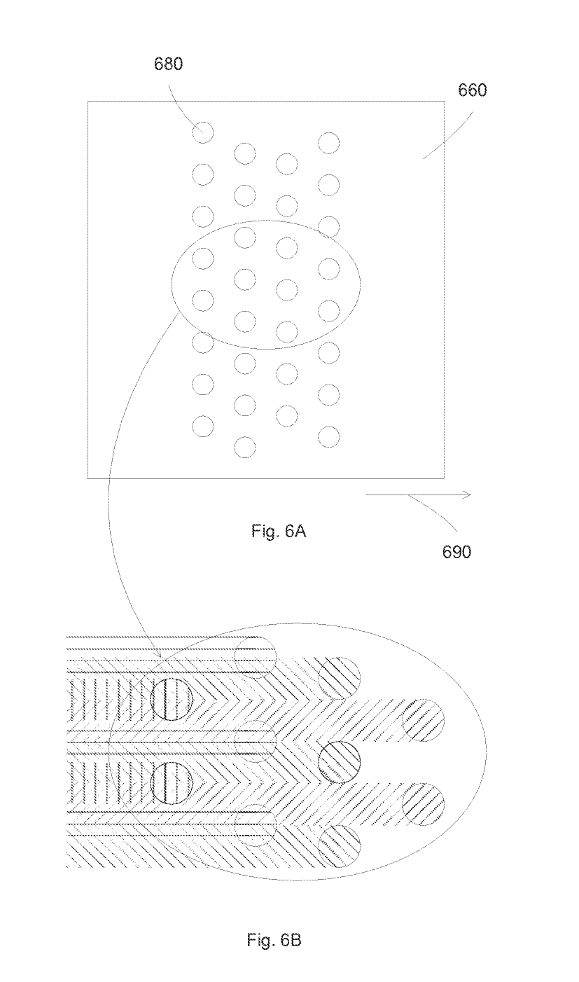

FIGS. 6A-6B illustrate an exemplary collimator according to some embodiments of the present invention. In FIG. 6A, a collimator 660 comprises a plurality of apertures 680, which are disposed in a zigzag fashion to ensure a complete coverage of material when the substrate travels along direction 690. In FIG. 6B, an exemplary pattern of staggered apertures is shown, providing complete coverage when the sputtered particles are deposited on the moving substrate. Other collimator configurations can be used, such as larger apertures for overlapping between rows of apertures, or more rows of apertures.

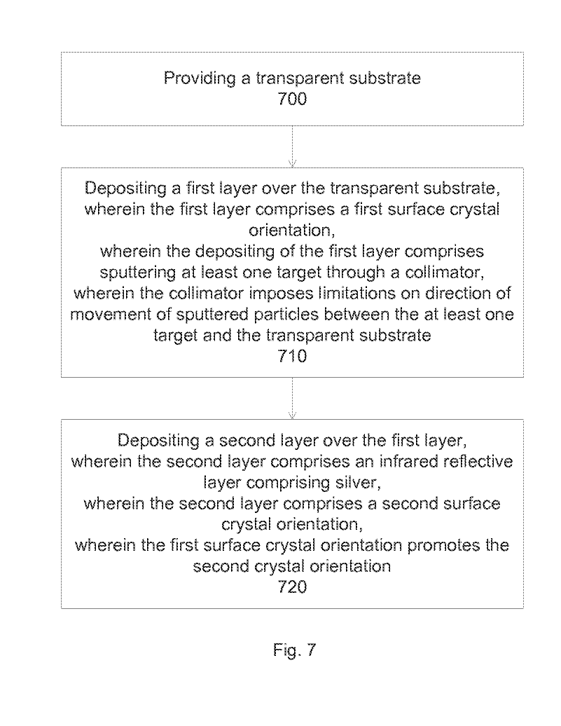

FIG. 7 illustrates an exemplary flow chart for collimated sputtering according to some embodiments of the present invention. In operation 700, a transparent substrate is provided. In operation 710, a first layer is deposited through a collimator over the substrate. The first layer can comprise a surface crystal orientation, and is formed by sputtering one target through a collimator, wherein the collimator imposes limitations on direction of movement of sputtered particles between the one target and the transparent substrate. In operation 720, a second layer is deposited over the first layer. The second layer can comprise an infrared reflective layer comprising silver, and having a surface crystal orientation that can be promoted by the surface crystal orientation of the seed layer.

In some embodiments, other layers can be included, such as a protective layer, an oxide layer, a barrier layer, an antireflective oxide, an optical filler layer, an interface layer and an adhesion layer. The additional layers can be sputtered deposited through a collimator to reduce roughness.

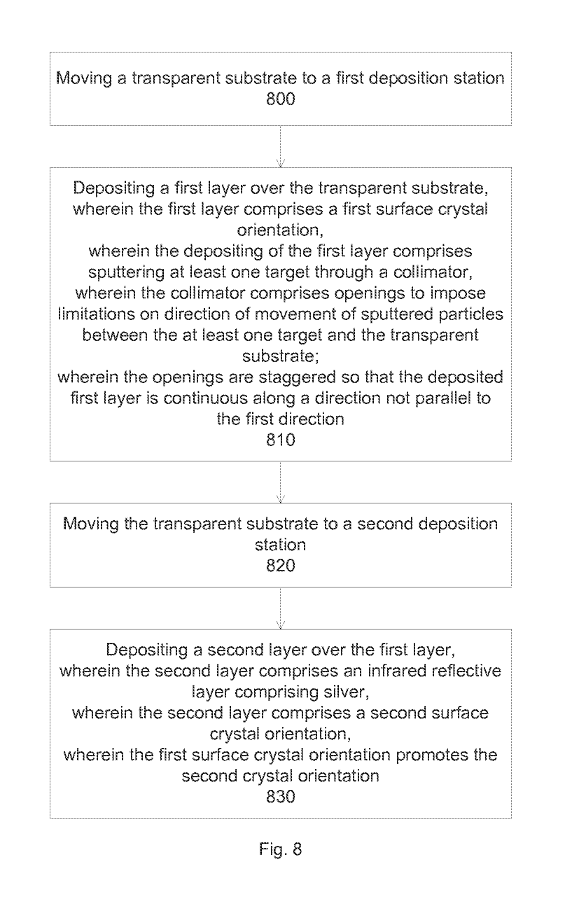

FIG. 8 illustrates another exemplary flow chart for collimated sputtering according to some embodiments of the present invention. In operation 800, a transparent substrate is moved to a first deposition station, for example, by a transfer mechanism. In operation 810, a first layer is deposited through a collimator over the substrate. The first layer can comprise a surface crystal orientation, and is formed by sputtering one target through a collimator, wherein the collimator comprises openings to impose limitations on direction of movement of sputtered particles between the target and the transparent substrate, and wherein the openings are staggered so that the deposited first layer is continuous along a direction not parallel to the first direction. In operation 820, the transparent substrate is moved to a second deposition station. In operation 830, a second layer is deposited over the first layer. The second layer can comprise an infrared reflective layer comprising silver, and having a surface crystal orientation that can be promoted by the surface crystal orientation of the first layer.

In some embodiments, other layers can be included, such as a protective layer, an oxide layer, a barrier layer, an antireflective oxide, an optical filler layer, an interface layer and an adhesion layer. The additional layers can be sputtered deposited through a collimator to reduce roughness.

The present collimated sputtering has been proven to provide low sheet resistance for a low emissivity stack. For example, a silver layer of 8 nm thickness has been fabricated having resistivity of less than 4.7 μΩ-cm, resulting in a stack having sheet resistance of less than 5.8Ω/□.

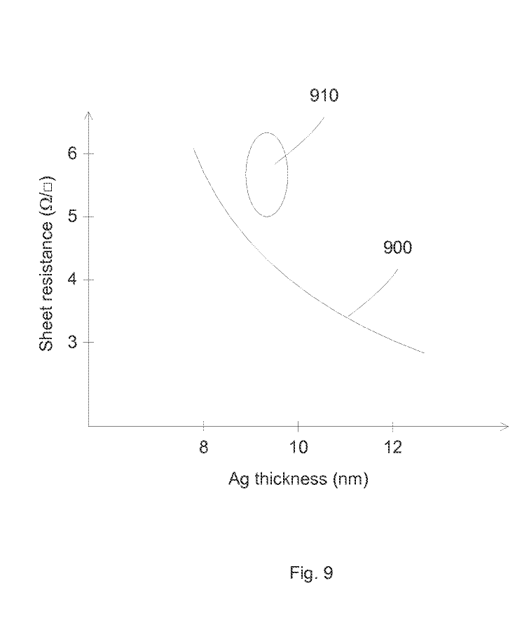

FIG. 9 illustrates exemplary sheet resistance for low emissivity stacks according to some embodiments of the present invention. Low sheet resistance 900 can be achieved using the present collimated sputtering, as compared to non-collimated sputtering 910.

Although the foregoing examples have been described in some detail for purposes of clarity of understanding, the invention is not limited to the details provided. There are many alternative ways of implementing the invention. The disclosed examples are illustrative and not restrictive.

What is claimed:

1. A method for making a coated article, the method comprising:
providing a transparent substrate;
depositing a first layer over the transparent substrate,
wherein the first layer comprises a first surface crystal orientation,
wherein the depositing of the first layer comprises sputtering at least one target through a collimator,
wherein the collimator imposes limitations on direction of movement of sputtered particles between the at least one target and the transparent substrate; and
depositing a second layer over the first layer,
wherein the second layer comprises silver,
wherein the second layer comprises a second surface crystal orientation.

2. A method as in claim 1, wherein the collimator limits the angles of the sputter particles reaching the substrate to a range of ±0.25 steradians.

3. A method as in claim 1, wherein the thickness of the first layer is less than 10 nm.

4. A method as in claim 1, wherein the thickness of the second layer is less than 10 nm.

5. A method as in claim 1, wherein the first layer comprises ZnO.

6. A method as in claim 1, further comprising
depositing an third between the substrate and the first layer.

7. A method as in claim 1, further comprising
depositing a fourth layer over the second layer, wherein the fourth layer comprises a metallic layer or an alloy metal layer.

8. A method as in claim 1, further comprising
depositing a dielectric layer over the second layer.

9. A method as in claim 1, wherein the depositing of the second layer comprises sputtering a silver target through the collimator.

10. A method for making a coated article, the method comprising:
moving a transparent substrate to a first station;
depositing a first layer over the transparent substrate,
wherein the first layer comprises a first surface crystal orientation,
wherein the depositing of the first layer comprises sputtering at least one target through a collimator,
wherein the collimator comprises openings to impose limitations on direction of movement of sputtered particles between the at least one target and the transparent substrate;
wherein the openings are staggered so that the deposited first layer is continuous along a direction not parallel to the first direction;
depositing a second layer over the first layer, and
wherein the second layer comprises silver,
wherein the second layer comprises a second surface crystal orientation.

11. A method as in claim 10, wherein the collimator limits the angles of the sputter particles reaching the substrate to a range of ±0.25 steradians.

12. A method as in claim 10, wherein the first layer comprises ZnO.

13. A method as in claim 10, further comprising
depositing an third between the substrate and the first layer.

14. A method as in claim 10, further comprising
depositing a fourth layer over the second layer, wherein the fourth layer comprises a metallic layer or an alloy metal layer.

15. A method as in claim 10, further comprising
depositing a dielectric layer over the second layer.

16. A method as in claim 10, wherein the depositing of the second layer comprises sputtering a silver target through the collimator.

17. An apparatus for coating an article, the apparatus comprising:
a mechanism for moving a substrate in a first direction;
at least one first target for sputtering a first layer on the substrate;
a collimator disposed between the at least one first target and the substrate,
wherein the collimator comprises openings to impose limitations on direction of movement of sputtered particles between the at least one target and the substrate;
wherein the openings are staggered along the first direction so that the layer is continuous along a second direction not parallel to the first direction.
at least one second target for sputtering a second layer over the first layer.

18. An apparatus as in claim 17, wherein the collimator limits the angles of the sputter particles reaching the substrate to a range of ±0.25 steradians.

19. An apparatus as in claim 17, wherein the first target comprises ZnO.

20. An apparatus as in claim 17, wherein the second target comprises silver.
